(19) United States
(12) Patent Application Publication
(10) Pub. No.: US 2008/0157390 A1
(43) Pub. Date: Jul. 3, 2008

(54) METHOD OF FORMING LOW-K DIELECTRIC LAYER AND STRUCTURE THEREOF

(76) Inventor: Jong Taek Hwang, Chungcheongbuk-do (KR)

Correspondence Address: SHERR & NOURSE, PLLC, 620 HERNDON PARKWAY, SUITE 200, HERNDON, VA, 20170, US

(21) Appl. No.: 11/932,141

(22) Filed: Oct. 31, 2007

(30) Foreign Application Priority Data
Dec. 29, 2006 (KR) 10-2006-0137356

(51) Int. Cl. H01L 23/48; H01L 21/4763

(52) U.S. Cl. 257/774; 438/637; 257/E21.495; 257/E23.01

(57) ABSTRACT

A method of forming a low-k dielectric layer and structure thereof are disclosed. The present invention forms a BSG layer containing fluorine as an insulating interlayer beneath an FSG layer to enable the BSG layer to capture fluorine diffusing from the FSG layer. Accordingly, the present invention is able to effectively prevent such a problem as a dielectric constant increase of a lower insulating interlayer due to fluorine diffusion, signal transfer characteristic degradation, poor adhesion between the lower insulating interlayer and a barrier metal layer, delamination due to the poor adhesion, and the like.

The present application claims priority under 35 U.S.C. 119 to Korean Patent Application No. 10-2006-0137356 (filed on Dec. 29, 2006), which is hereby incorporated by reference in its entirety.

### BACKGROUND

Aspects of semiconductor technology have focused on increasing functionality and integration. Reducing spatial gaps metal interconnects lines plays a role in achieving such functionality and integration. The spatial gap may be filled with an insulating interlayer composed of a material such as silicon oxide for electrical insulation. Silicon oxide has a relatively high dielectric constant, and thus, the spatial gap between metal interconnects can be reduced, however, parasitic capacitance between lines adjacent to each other may increases to higher levels and bring about signal delay.

In order to overcome signal delay, an insulating interlayer may be formed of a material such as fluorinated silica glass (FSG) having a low dielectric constant (low-k). FSG may be formed by doping undoped silica glass (USG) with fluorine. The dielectric constant of FSG is only about 3.5, which makes FSG useful as an insulating interlayer.

Fluorine, however, has very good mobility, thereby causing problems of diffusing into another insulating interlayer.

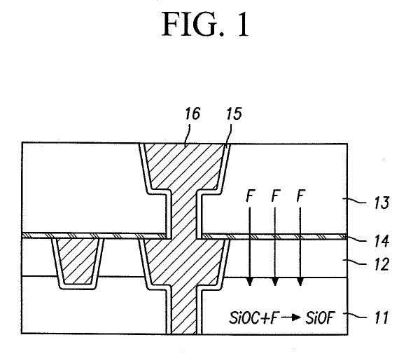

As illustrated in example FIG. 1, a lower insulating interlayer has a multi-layer structure including silicon oxycarbide (SiOC) layer 11 and undoped silica glass (USG) layer 12. Capping layer 14 and an upper insulating interlayer 13 composed of FSG may be formed on and/or over the lower insulating interlayer. Copper metal interconnect 16 having a dual damascene structure may be embedded in insulating interlayers 11, 12, and 13. Barrier metal layer 15 may be inserted between the metal interconnect 16 and insulating interlayers 11, 12, and 13.

Such a configuration, however, may cause fluorine diffusion of the FSG insulating interlayer, thereby resulting in failure in the lower insulating interlayer. This problem is caused by defects such as a plurality of pinholes formed in capping layer 14. The fluorine contained in FSG layer 13 diffuses into lower insulating interlayers 11 and 12 via the pinholes. The diffusing fluorine is then bonded to carbon provided in the low-k dielectric SiOC layer 11 to form SiOF. Because the dielectric constant of SiOF is greater than that of SiOC, SiOF degrades the signal transfer characteristic. Moreover, SiOF, which has poor adhesion to the barrier metal layer 15 of the metal interconnect 16 may cause delamination.

### SUMMARY

Embodiments relate to a method of forming a low-k dielectric layer and structure thereof, whereby a lower insulating interlayer is protected against diffusion of fluorine contained in an FSG insulating interlayer to avoid signal transfer characteristic degradation and delamination due to low adhesion between the lower insulating interlayer and a barrier metal layer.

Embodiments relate to a method of forming a low-k insulating interlayer including at least one of the following steps: depositing a first lower insulating interlayer over a substrate; depositing a second lower insulating interlayer containing a p-type dopant over the first lower insulating interlayer; forming a first copper interconnect extending through the first lower insulating interlayer and the second lower insulating interlayer; depositing a capping layer over the second lower insulating interlayer; forming an upper insulating interlayer containing fluorine over the capping layer; and then forming a second metal interconnect extending through the upper insulating interlayer.

Embodiments relate to a low-k insulating interlayer comprising: a first lower insulating interlayer formed over a substrate; a second lower insulating interlayer containing a p-type dopant formed over the first lower insulating interlayer; a first metal interconnect formed extending through the first lower insulating interlayer and the second lower insulating interlayer; a capping layer formed over the second lower insulating interlayer; an upper insulating interlayer containing fluorine formed over the capping layer; and a second metal interconnect formed extending through the upper insulating interlayer and in connection with the first metal interconnect.

Embodiments relate to a method of forming low-k insulating interlayer comprising at least one of the following steps: forming a lower insulating interlayer over a substrate; forming a first barrier metal layer and a first metal interconnect each extending through the lower insulating interlayer by conducting a first dual damascene process on the lower insulating interlayer; forming a capping layer over the lower insulating interlayer; forming an upper insulating interlayer over the capping layer; and then forming a second barrier metal layer and a second metal interconnect each extending through the upper insulating interlayer by conducting a second dual damascene process on the upper insulating interlayer. In accordance with embodiments, the second barrier metal can be connected to the first barrier metal and the second metal interconnect can be connected to the first metal interconnect.

### DRAWINGS

Example FIG. 1 illustrates fluorine diffusion of an FSG insulating interlayer of low-k causing failure of a lower insulating interlayer.

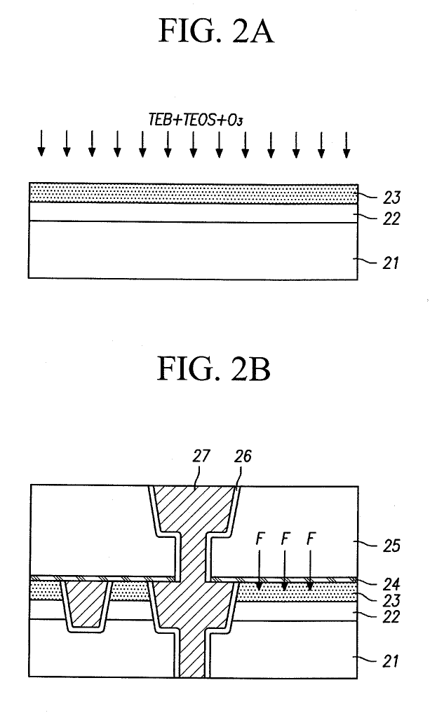

Example FIGS. 2A and 2B illustrate a method of forming a low-k dielectric insulating interlayer and structure thereof, in accordance with embodiments.

### DESCRIPTION

As illustrated in example FIG. 2A, a lower insulating interlayer can be formed by sequentially depositing silicon oxycarbide (SiOC) layer 21 and undoped silica glass (USG) layer 22 on and/or over a substrate. Boron-doped silicate glass (BSG) layer 23 can then be deposited on and/or over USG layer 22.

BSG layer 23 can be deposited using thermal chemical vapor deposition. The deposition can be conducted using reaction gases of O₃, TEOS (tetraethylortosilicate), and TEB (triethylborate). The BSG layer 23 can be deposited using gas flow of between approximately 4300 to 4700 scc of O₃, between approximately 500 to 1000 mgm of TEOS, between approximately 155 to 160 mgm of TEB, between approximately 4000 scc of N₂—C: and between approximately 2000 scc of H₂—C. The thermal CVD can be conducted at a temperature of between approximately 450 to 500° C. for at deposition time of between approximately 10 to 15 seconds.

Using thermal CVD, O₃ and Si react with each other to form SiO₂. Boron dissolved from TEB diffuses as a P-type dopant into SiO₂, thereby forming boron-doped BSG layer 23.

As illustrated in example FIG. 2B, a dual damascene process can be conducted on and/or over the lower insulating interlayer including SiOC layer 21, USG layer 22 and BSG layer 23, thereby forming barrier metal layer 26 and metal interconnect 27. Metal interconnect 27 may be composed of copper (Cu).

Subsequently, capping layer 24 can be deposited on and/or over the lower insulating interlayer including SiOC layer 21, USG layer 22 and BSG layer 23 provided with copper metal interconnect 27. Fluorinated silica glass (FSG) layer 25 can then be deposited as an upper insulating interlayer on and/or over capping layer 24.

Like the lower insulating interlayer, a dual damascene process can be conducted on and/or over upper insulating interlayer 25 to complete barrier metal layer 26 and copper interconnect 27.

In accordance with embodiments, the insulating interlayer structure, defects such as a plurality of pinholes may be generated in capping layer 24. However, even if the fluorine provided in FSG layer 25 diffuses via the pinholes, BSG layer 23 serves to capture the fluorine to prevent any instances of failure due to fluorine diffusion.

This occurs due to the boron provided in BSG layer 23 having good reactivity with fluorine. Thus, boron can be easily bonded to fluorine to form BF₃. If BSG layer 23 is formed beneath the upper insulating interlayer 25, fluorine diffusing via the pinholes in capping layer 24 may become bonded to carbon in SiOC layer 21, thereby forming SiOF.

BSG layer 23 has poor adhesion to SiOC layer 21, which may induce delamination. Thus, it is not preferable that USG layer 22 is entirely replaced by BSG layer 23. Instead, it is preferable that the thickness of USG layer 22 is reduced to one half and such that the reduced one half portion can be replaced by BSG layer 23. For instance, if USG layer 22 has a thickness of about 1,700 Å, USG layer 22 and BSG layer 23 may each have a thickness of approximately 850 Å.

In accordance with embodiments, a BSG layer may be formed including fluorine as an insulating interlayer beneath an FSG layer to enable the BSG layer to capture fluorine diffusing from the FSG layer. Accordingly, embodiments may effectively prevent an increase in a dielectric constant of a lower insulating interlayer due to fluorine diffusion, signal transfer characteristic degradation, poor adhesion between the lower insulating interlayer and a barrier metal layer and delamination due to the poor adhesion.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
depositing a first lower insulating interlayer over a substrate;
depositing a second lower insulating interlayer containing a p-type dopant over the first lower insulating interlayer;
forming a first copper interconnect extending through the first lower insulating interlayer and the second lower insulating interlayer;
depositing a capping layer over the second lower insulating interlayer;
forming an upper insulating interlayer containing fluorine over the capping layer; and then
forming a second metal interconnect extending through the upper insulating interlayer.

2. The method of claim 1, wherein the second lower insulating interlayer comprises a boron-doped silicate glass layer.

3. The method of claim 2, wherein the boron-doped silicate glass layer is deposited using thermal chemical vapor deposition having O₃, TEOS, and TEB as reactant gases.

4. The method of claim 3, wherein between approximately 4,300 to 4,700 sccm of the O₂ gas, between approximately 500 to 1,000 mgm of the TEOS gas, and between approximately 155 to 160 mgm of the TEB gas are used during the thermal chemical vapor deposition.

5. The method of claim 3, wherein the boron-doped silicate glass layer is deposited for between approximately 10 to 15 seconds at a temperature of between approximately 450 to 500° C.

6. The method of claim 1, wherein the first lower insulating interlayer is configured to have a multilayer structure comprising an SiOC layer and a undoped silica glass layer, and the upper insulating interlayer comprises a fluorinated silica glass layer.

7. The method of claim 1, wherein the first metal interconnect and the second metal interconnect each comprise copper.

8. An apparatus comprising:
a first lower insulating interlayer formed over a substrate;
a second lower insulating interlayer containing a p-type dopant formed over the first lower insulating interlayer;
a first metal interconnect formed extending through the first lower insulating interlayer and the second lower insulating interlayer;
a capping layer formed over the second lower insulating interlayer;
an upper insulating interlayer containing fluorine formed over the capping layer; and
a second metal interconnect formed extending through the upper insulating interlayer and in connection with the first metal interconnect.

9. The apparatus of claim 8, wherein the first lower insulating interlayer comprises a silicon oxycarbide layer and a undoped silica glass layer, the second lower insulating interlayer comprises a boron-doped silicate glass layer, and the upper insulating interlayer comprises a fluorinated silica glass layer.

10. A method comprising:
forming a lower insulating interlayer over a substrate;
forming a first barrier metal layer and a first metal interconnect each extending through the lower insulating interlayer by conducting a first dual damascene process on the lower insulating interlayer;
forming a capping layer over the lower insulating interlayer;
forming an upper insulating interlayer over the capping layer; and then
forming a second barrier metal layer and a second metal interconnect each extending through the upper insulating interlayer by conducting a second dual damascene process on the upper insulating interlayer,
wherein the second barrier metal is connected to the first barrier metal and the second metal interconnect is connected to the first metal interconnect.

11. The method of claim 10, wherein forming the lower insulating layer comprises sequentially depositing a silicon oxycarbide layer and an undoped silica glass layer over the substrate and depositing a boron-doped silicate glass layer over the undoped silica glass layer.

12. The method of claim 11, wherein the undoped silica glass layer and the boron-doped silicate glass layer each have a respective thickness of approximately 850 Å.

13. The method of claim 12, wherein the boron-doped silicate glass layer is deposited using chemical vapor deposition.

14. The method of claim 13, wherein the chemical vapor deposition comprises thermal chemical vapor deposition.

15. The method of claim 14, wherein the thermal chemical vapor deposition is conducted using reaction gases of O₃, tetraethylortosilicate, and triethylborate.

16. The method of claim 15, wherein the thermal chemical vapor deposition is conducted using a gas flow of between approximately 4300 to 4700 scc of O₃, between approximately 500 to 1000 mgm of tetraethylortosilicate, and between approximately 155 to 160 mgm of triethylborate.

17. The method of claim 16, wherein the thermal chemical deposition is conducted at a temperature of between approximately 450 to 500° C. for between approximately 10 to 15 seconds.

18. The method of claim 10, wherein the first metal interconnect and the second metal interconnect each comprises copper.

19. The method of claim 10, wherein the upper insulating interlayer comprises fluorinated silica glass.
